(19) United States
(12) Patent Application Publication
(10) Pub. No.: US 2026/0059765 A1
(43) Pub. Date: Feb. 26, 2026

(54) MAGNETIC MEMORY DEVICE AND METHOD FOR FABRICATING THE SAME

(71) Applicant: Samsung Electronics Co., Ltd., Suwon-si (KR)

(72) Inventors: Young Keol KIM, Suwon-si (KR); Hyun Chul SHIN, Suwon-si (KR); Won Hyeok HEO, Suwon-si (KR)

(73) Assignee: Samsung Electronics Co., Ltd., Suwon-si (KR)

(21) Appl. No.: 19/194,883

(22) Filed: Apr. 30, 2025

(30) Foreign Application Priority Data
Aug. 20, 2024 (KR) 10-2024-0111455

(51) Int. Cl. H10B 61/00; H10N 50/01; H10N 50/10; H10N 50/80

(52) U.S. Cl. CPC H10B 61/10; H10N 50/01; H10N 50/10; H10N 50/80

(57) ABSTRACT

A magnetic memory device includes a substrate, a base insulating film on the substrate, a magnetic tunnel junction element including first and second magnetic patterns and a tunnel barrier pattern therebetween on the base insulating film, an upper electrode pattern on an upper face of the magnetic tunnel junction element, a capping structure including a first to third capping films sequentially stacked on a side face of the magnetic tunnel junction element, and a conductive line on both the upper electrode pattern and the capping structure and connected to the upper electrode pattern. An uppermost end of the second capping film is higher than an uppermost end of the first capping film, an uppermost end of the third capping film is lower than the uppermost end of the first capping film, and the second capping film includes a material different from respective materials of the first and third capping films.

### CROSS-REFERENCE TO RELATED APPLICATION

This application claims priority from Korean Patent Application No. 10-2024-0111455 filed on Aug. 20, 2024 in the Korean Intellectual Property Office and all the benefits accruing therefrom under 35 U.S.C. 119, the contents of which in its entirety are herein incorporated by reference.

### BACKGROUND

### 1. Field

The present inventive concepts relate to magnetic memory devices and methods for fabricating the same. More specifically, the present inventive concepts relate to magnetic memory devices including a capping film and methods for fabricating the same.

### 2. Description of the Related Art

With high speed and low power consumption of electronic devices, memory devices built into them also require rapid read/write operations and low operating voltages. Magnetic memory devices are being researched as the memory devices that satisfy such requirements. The magnetic memory devices are non-volatile, capable of performing a high-speed operation, and are attracting attention as next-generation memories.

Meanwhile, as the magnetic memory devices become more and more highly integrated, STT-MRAM, which stores information by the use of a spin transfer torque (STT) phenomenon, is being researched. The STT-MRAM may induce a magnetization reversal by applying a current directly to a magnetic tunnel junction element to store information. Highly integrated STT-MRAM requires a high-speed operation and a low current operation.

### SUMMARY

Some example embodiments of the present inventive concepts provide a magnetic memory device having improved element characteristics and process margins.

Some example embodiments of the present inventive concepts provide a method for fabricating a magnetic memory device having improved element characteristics and process margins.

According to some example embodiments of the present inventive concepts, a magnetic memory device may include a substrate, a base insulating film on the substrate, a magnetic tunnel junction element which includes a first magnetic pattern, a tunnel barrier pattern, and a second magnetic pattern that are sequentially stacked on the base insulating film, an upper electrode pattern on an upper face of the magnetic tunnel junction element, a capping structure which includes a first capping film, a second capping film, and a third capping film that are sequentially stacked on a side face of the magnetic tunnel junction element, and a conductive line connected to the upper electrode pattern, on the upper electrode pattern and the capping structure. An uppermost end of the second capping film may be higher than an uppermost end of the first capping film. An uppermost end of the third capping film maybe lower than the uppermost end of the first capping film. The second capping film may include a material different from respective materials of the first capping film and the third capping film.

According to some example embodiments of the present inventive concepts, a magnetic memory device may include a substrate, a base insulating film on the substrate, a first memory cell and a second memory cell which are spaced apart from each other on the base insulating film and each include a magnetic tunnel junction element and an upper electrode pattern that are sequentially stacked on the base insulating film, a capping structure which includes a first capping film, a second capping film, and a third capping film that are sequentially stacked on a side face of the first memory cell and a side face of the second memory cell, and a conductive line which is connected to the upper electrode pattern on the first memory cell and the second memory cell. The first capping film may further extend along an upper face of the base insulating film between the first memory cell and the second memory cell. The second capping film and the third capping film may expose a part of the first capping film extending along the upper face of the base insulating film. The second capping film may include a material different from respective materials of the first capping film and the third capping film.

According to some example embodiments of the present inventive concepts, a magnetic memory device may include a substrate including a first region and a second region, a first transistor on the first region, a second transistor on the second region, a lower insulating film on both the first transistor and the second transistor, a base insulating film on the lower insulating film on the first region, a memory cell which includes a lower electrode pattern, a magnetic tunnel junction element, and an upper electrode pattern that are sequentially stacked on the base insulating film, and is electrically connected to the first transistor, a capping structure which includes a first capping film, a second capping film, and a third capping film that are sequentially stacked on a side face of the memory cell, a conductive line which is connected to the upper electrode pattern on the memory cell and the capping structure, an upper insulating film on the lower insulating film on the second region, and an upper wiring pattern which is electrically connected to the second transistor inside the upper insulating film. The capping structure may not extend along an upper face of the lower insulating film on the second region. The second capping film may include a material different from respective materials of the first capping film and the third capping film.

However, example embodiments of the present inventive concepts are not restricted to the ones set forth herein. The above and other aspects of the present inventive concepts will become more apparent to one of ordinary skill in the art to which the present inventive concepts pertain by referencing the detailed description of the present inventive concepts given below.

### BRIEF DESCRIPTION OF THE DRAWINGS

FIG. 1 is an example circuit diagram for explaining a magnetic memory device according to some example embodiments.

FIG. 2 is an example layout diagram for explaining a magnetic memory device according to some example embodiments.

FIG. 3 is a cross-sectional view taken along A1-A1 and B1-B1 of FIG. 2.

FIG. 4 is an enlarged view for explaining a region R of FIG. 3.

FIG. 5 is a cross-sectional view taken along A2-A2 and B2-B2 of FIG. 2.

FIGS. 6 and 7 are diagrams for explaining a magnetic tunnel junction element of the magnetic memory device according to some example embodiments.

FIGS. 8A, 8B, 8C, and 8D are various enlarged views for explaining a magnetic memory device according to some example embodiments.

FIGS. 9, 10, 11, 12, 13, 14, 15, 16, and 17 are intermediate step diagrams for explaining the method for fabricating the magnetic memory device according to some example embodiments.

### DETAILED DESCRIPTION

Hereinafter, example embodiments will be explained in detail with reference to the accompanying drawings. To clearly describe the present inventive concepts, parts that are irrelevant to the description in the drawings are omitted. The same reference numerals are used for the same components in the drawings, and redundant descriptions thereof are omitted. Further, since sizes and thicknesses of constituent members shown in the accompanying drawings are arbitrarily given for better understanding and case of description, the present inventive concepts are not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, plate, etc. is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that surfaces which may be referred to as being “flat” may be understood to be “planar” or “substantially planar.” It will be understood that surfaces which may be referred to as being “planar” may be “planar” or may be “substantially planar.” Surfaces that are “substantially planar” will be understood to be “planar” within manufacturing tolerances and/or material tolerances and/or have surface portions with a deviation in magnitude and/or angle from “planar,” respectively, with regard to the other portions of the surfaces that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

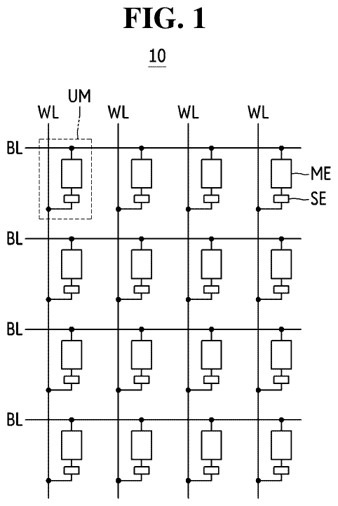

Hereinafter, a magnetic memory device according to example embodiments will be described referring to FIGS. 1 to 8D.

FIG. 1 is an example circuit diagram for explaining a magnetic memory device 10 according to some example embodiments.

Referring to FIG. 1, the magnetic memory device 10 according to some example embodiments may include a plurality of bit lines BL, a plurality of word lines WL, and a plurality of unit memory cells UM.

The plurality of bit lines BL and the plurality of word lines WL may intersect each other. For example, each of the word lines WL may extend in a first direction, and each of the bit lines BL may extend in a second direction intersecting the first direction.

The plurality of unit memory cells UM may be arranged two-dimensionally or three-dimensionally. For example, each unit memory cell UM may be connected to an intersection between the word lines WL and the bit lines BL intersecting each other. Each unit memory cell UM may include a magnetic tunnel junction element ME and a selection element SE.

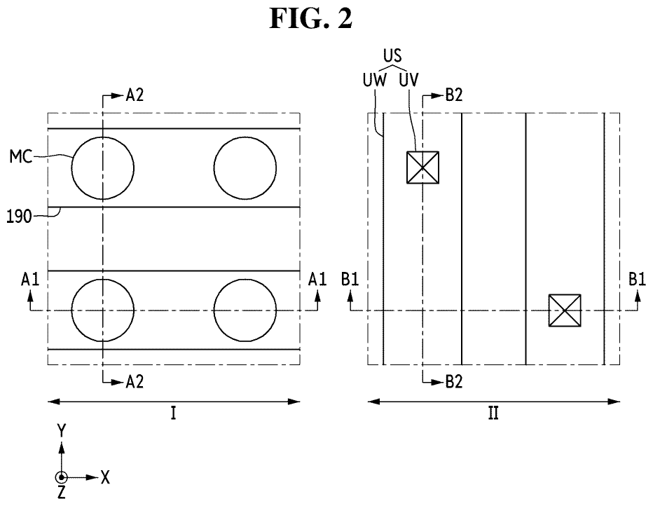

The magnetic tunnel junction element ME may be connected between the bit line BL and the selection element SE. The selection element SE may be connected between the magnetic tunnel junction element ME and the word line WL. The magnetic tunnel junction element ME may include a reference layer, a free layer, and a tunnel barrier film. The magnetic tunnel junction element ME will be described below in more detail in the description of FIGS. 2 to 7.

The selection element SE may be configured to selectively control the flow of charge that flows through the magnetic tunnel junction element ME. For example, the selection element SE may include at least one of a diode, a PNP bipolar transistor, an NPN bipolar transistor, an NMOS field effect transistor, a PMOS field effect transistor, or a combination thereof. When the selection element SE is made up a bipolar transistor or a MOS field effect transistor that is a three-terminal element, an additional wiring (e.g., a source line) may be connected to the selection element SE.

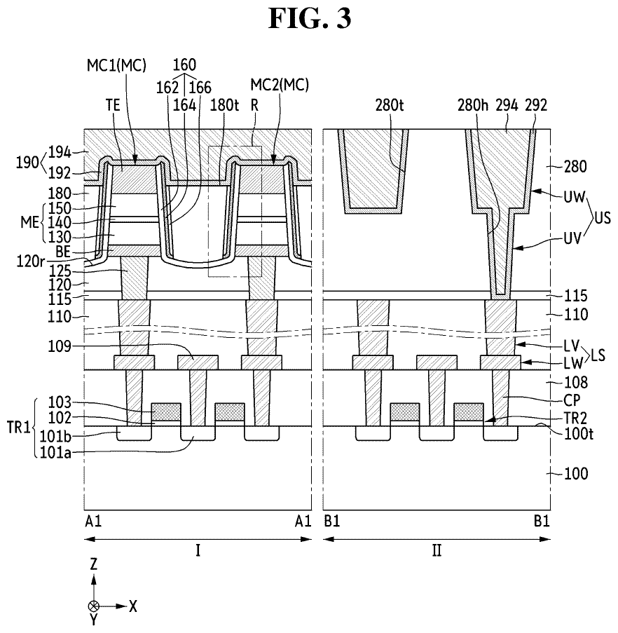

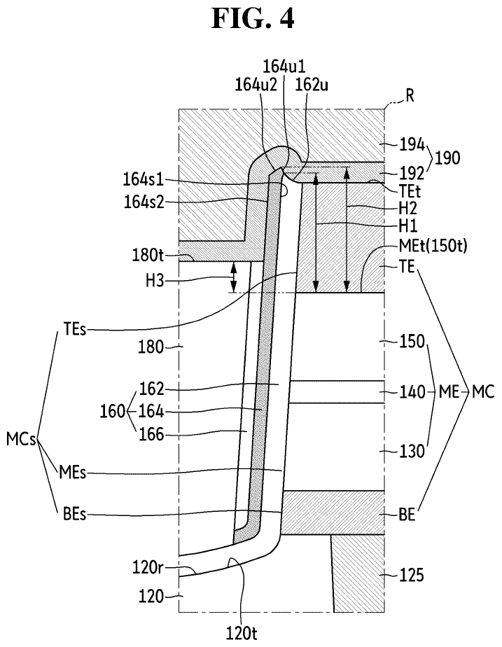

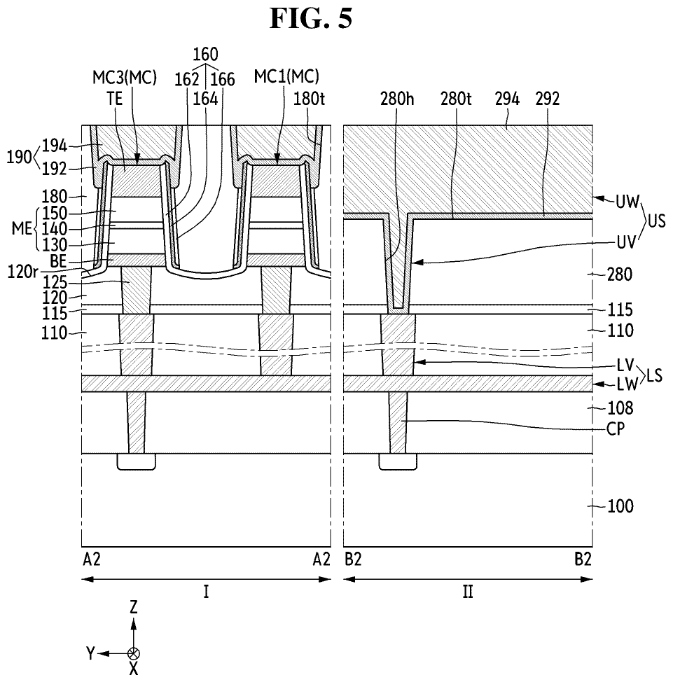

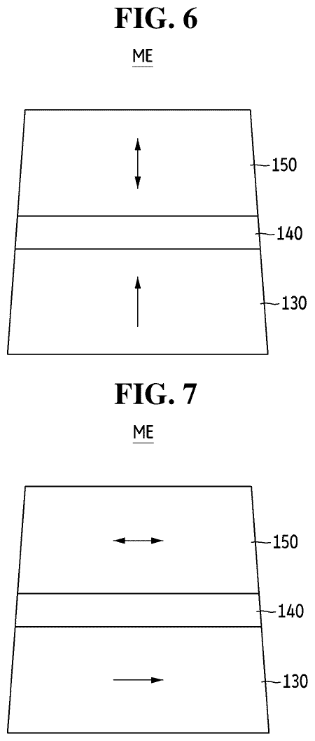

FIG. 2 is an example layout diagram for explaining a magnetic memory device according to some example embodiments. FIG. 3 is a cross-sectional view taken along A1-A1 and B1-B1 of FIG. 2. FIG. 4 is an enlarged view for explaining a region R of FIG. 3. FIG. 5 is a cross-sectional view taken along A2-A2 and B2-B2 of FIG. 2. FIGS. 6 and 7 are diagrams for explaining a magnetic tunnel junction element of the magnetic memory device according to some example embodiments.

Referring to FIGS. 2 to 7, the magnetic memory device according to some example embodiments includes a substrate 100, a first transistor TR1, a second transistor TR2, an interlayer insulating film 108, a contact pattern CP, a lower insulating film 110, a lower wiring structure LS, an etching stop film 115, a base insulating film 120, a plurality of memory cells MC, a capping structure 160, a filling insulating film 180, a first conductive line 190, an upper insulating film 280, and an upper wiring structure US.

The substrate 100 may be bulk silicon or silicon-on-insulator (SOI). In some example embodiments, the substrate 100 may be a silicon substrate or may include other materials, for example, silicon germanium, silicon germanium-on-insulator (SGOI), indium antimonide, lead telluride, indium arsenide, indium phosphide, gallium arsenide or gallium antimonide. In some example embodiments, the substrate 100 may be an epitaxial layer formed on a base substrate. As an example, the substrate 100 will be described as a silicon substrate in the following description.

The substrate 100 may include (e.g., may define) a first region I and a second region II. The first region I and the second region II may be regions connected to each other or may be regions spaced apart from each other.

The first transistor TR1 may be formed on the first region I of the substrate 100. The second transistor TR2 may be formed on the second region II of the substrate 100. The first transistor TR1 and the second transistor TR2 may each include a MOS field effect transistor. For example, the first transistor TR1 may include a first source/drain region 101a, a second source/drain region 101b, a gate dielectric film 102, and a gate electrode 103. The first source/drain region 101a and the second source/drain region 101b may be disposed on both sides (e.g., opposite sides) of the gate electrode 103, respectively. The gate dielectric film 102 may be interposed between the substrate 100 and the gate electrode 103.

Although each of the first transistor TR1 and the second transistor TR2 is only shown as being a planar field effect transistor, example embodiments are not limited thereto. Unlike the shown example, the first transistor TR1 and the second transistor TR2 may each have a fin-shaped field effect transistor (FinFET) having a fin-shaped channel, a field effect transistor including a nanowire or nanosheet-shaped channel, an MBCFET® including a multi-bridge channel, a VFET (Vertical FET), a CFET (Complementary FET), a three-dimensional (3D) transistor, or the like.

In some example embodiments, the first transistor TR1 and the second transistor TR2 may be formed at the same level. In this specification, the term “the same level” means a level formed by the same fabricating process.

In some example embodiments, the first transistor TR1 may be provided as a selection element (SE of FIG. 1) of a unit memory cell (UM of FIG. 1). For example, the gate electrode 103 of the first transistor TR1 may be provided on a word line (WL of FIG. 1) of the magnetic memory device and configured to selectively control the memory cell MC connected to the first transistor TR1.

The interlayer insulating film 108 may be formed on the first region I and the second region II. The interlayer insulating film 108 may cover the first transistor TR1 and the second transistor TR2. The interlayer insulating film 108 may include, for example, but is not limited to, at least one of silicon oxide, silicon nitride, silicon oxynitride, silicon oxycarbide, silicon boron nitride, silicon boron carbonitride, silicon oxycarbonitride, a low dielectric constant material having a lower dielectric constant than silicon oxide, or any combinations thereof. The low dielectric constant material may include, for example, but is not limited to, at least one of FOX (Flowable Oxide), TOSZ (Torene SilaZene), USG (Undoped Silica Glass), BSG (Borosilicate Glass), PSG (PhosphoSilicate Glass), BPSG (BoroPhosphoSilicate Glass), PETEOS (Plasma Enhanced Tetra Ethyl Ortho Silicate), FSG (Fluoride Silicate Glass), CDO (Carbon Doped silicon Oxide), Xerogel, Acrogel, Amorphous Fluorinated Carbon, OSG (Organo Silicate Glass), Parylene, BCB (bis-benzocyclobutenes), SiLK, polyimide, porous polymeric material, or any combinations thereof.

The contact pattern CP may be formed inside the interlayer insulating film 108. The contact pattern CP may be electrically connected to the first transistor TR1 and/or the second transistor TR2. For example, the contact pattern CP may be connected to the first source/drain region 101a, the second source/drain region 101b, and/or the gate electrode 103.

The lower insulating film 110 may be formed on the interlayer insulating film 108. The lower insulating film 110 may include, for example, but is not limited to, at least one of silicon oxide, silicon nitride, silicon oxynitride, silicon oxycarbide, silicon boron nitride, silicon boron carbonitride, silicon oxycarbonitride, a low dielectric constant material having a lower dielectric constant than silicon oxide, or any combinations thereof.

The lower wiring structure LS may be formed inside the lower insulating film 110. The lower wiring structure LS may be electrically connected to the first transistor TR1 and/or the second transistor TR2 through the contact pattern CP. The lower wiring structure LS may include lower wiring patterns LW of the multilayer, and a lower via pattern LV that interconnects the lower wiring patterns LW to each other. The number of layers, the number, the placement or the like of the lower wiring patterns LW and the lower wiring patterns LW are merely examples and are not limited to those shown in the drawings.

In some example embodiments, the lower wiring patterns LW on the first region I may include a second conductive line 109. The second conductive line 109 may be connected to the first source/drain region 101a through the contact pattern CP. The second conductive line 109 may be provided as a source line connected to the first transistor TR1 provided as the selection element (SE of FIG. 1).

The etching stop film 115 may be formed on the lower insulating film 110. The etching stop film 115 may extend conformally along an upper face of the lower insulating film 110. The etching stop film 115 may include, for example, but is not limited to, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), silicon carbonitride (SiCN), aluminum nitride (AlN), aluminum oxide (AIO), or any combination thereof.

The base insulating film 120 may be formed on the etching stop film 115 on the first region I. The base insulating film 120 may include, for example, but is not limited to, at least one of silicon oxide, silicon nitride, silicon oxynitride, silicon oxycarbide, silicon boron nitride, silicon boron carbonitride, silicon oxycarbonitride, a low dielectric constant material having a lower dielectric constant than silicon oxide, or any combinations thereof. As an example, the base insulating film 120 may include a silicon oxide film.

A plurality of memory cells MC may be formed on the base insulating film 120. The plurality of memory cells MC may be arranged two-dimensionally on a horizontal plane (e.g., an XY plane). For example, the plurality of memory cells MC may be arranged in a lattice shape along a first direction X and a second direction Y that are parallel to the upper face of the substrate 100 and intersect each other. Each memory cell MC may include a lower electrode pattern BE, a magnetic tunnel junction element ME, and an upper electrode pattern TE that are sequentially stacked on the base insulating film 120.

The magnetic tunnel junction element ME may include a first magnetic pattern 130, a tunnel barrier pattern 140, and a second magnetic pattern 150 that are sequentially stacked on the base insulating film 120, for example are sequentially stacked on the lower electrode pattern BE. The tunnel barrier pattern 140 may be interposed between the first magnetic pattern 130 and the second magnetic pattern 150. The first magnetic pattern 130 and the second magnetic pattern 150 may be spaced apart from each other (e.g., isolated from direct contact with each other) by the tunnel barrier pattern 140.

One of the first magnetic pattern 130 or the second magnetic pattern 150 may be a reference layer having a fixed magnetization direction regardless of an external magnetic field, and the other of the first magnetic pattern 130 and the second magnetic pattern 150 may be a free layer that is variable between two stable magnetization directions.

As an example, as shown in FIGS. 6 and 7, the first magnetic pattern 130 may be a reference layer having a fixed magnetization direction, and the second magnetic pattern 150 may be a free layer having a variable magnetization direction. However, this is merely an example, and it goes without saying that the first magnetic pattern 130 may be a free layer and the second magnetic pattern 150 may be a reference layer, unlike the shown example.

In some example embodiments, each of the first magnetic pattern 130 and the second magnetic pattern 150 may have perpendicular magnetic anisotropy (PMA). For example, each of the first magnetic pattern 130 and the second magnetic pattern 150 may include at least one of an intrinsic perpendicular magnetic material or an extrinsic perpendicular magnetic material. As an example, as shown in FIG. 6, each of the first magnetic pattern 130 and the second magnetic pattern 150 may have a magnetization easy axis in a perpendicular direction (e.g., the third direction Z). In FIG. 6, a one-way arrow of the first magnetic pattern 130 indicates that the magnetization direction of the first magnetic pattern 130 is fixed in the perpendicular direction, and a two-way arrow of the second magnetic pattern 150 indicates that the magnetization direction of the second magnetic pattern 150 may be magnetized to be parallel or antiparallel to the magnetization direction of the first magnetic pattern 130.

The intrinsic perpendicular magnetic material may refer to a material that has perpendicular magnetization characteristics even in the absence of external factors. For example, the intrinsic perpendicular magnetic material may include at least one of i) perpendicular magnetic materials (as an example, CoFeTb, CoFeGd, and CoFeDy), ii) perpendicular magnetic materials having an L1₀ structure, iii) CoPt of a hexagonal close packed lattice structure, and iv) a perpendicular magnetic structure. The perpendicular magnetic materials having the L1₀ structure may include, for example, FePt of the L1₀ structure, FePd of the L1₀ structure, CoPd of the L1₀ structure, CoPt of the L1₀ structure, and the like. The perpendicular magnetic structure may include magnetic films and non-magnetic films that are alternately and repeatedly stacked. For example, the perpendicular magnetic structure may include (Co/Pt)ₙ, (CoFe/Pt)ₙ, (CoFe/Pd)ₙ, (Co/Pd)ₙ, (Co/Ni)ₙ, (CoNi/Pt)ₙ, (CoCr/Pt)ₙ, or (CoCr/Pd)ₙ (here, n is the number of layers).

The extrinsic perpendicular magnetic material may refer to a material that has an intrinsic horizontal magnetization characteristics but has a perpendicular magnetization characteristics due to an external factor. For example, the extrinsic perpendicular magnetic material may have a perpendicular magnetic anisotropy (i.e., interfacial perpendicular magnetic anisotropy (i-PMA)) induced by the junction with the tunnel barrier pattern 140. The extrinsic perpendicular magnetic material may include, but not limited to, CoFeB or CoFe.

In some example embodiments, each of the first magnetic pattern 130 and the second magnetic pattern 150 may have an in-plane magnetic anisotropy (IMA). As an example, as shown in FIG. 7, each of the first magnetic pattern 130 and the second magnetic pattern 150 may have a magnetization easy axis in a horizontal direction (e.g., the first direction X or the second direction Y). In FIG. 7, the one-way arrow of the first magnetic pattern 130 indicates that the magnetization direction of the first magnetic pattern 130 is fixed in the horizontal direction, and the two-way arrow of the second magnetic pattern 150 indicates that the magnetization direction of the second magnetic pattern 150 may be magnetized to be parallel or antiparallel to the magnetization direction of the first magnetic pattern 130.

Each of the first magnetic pattern 130 and the second magnetic pattern 150 having in-plane magnetic anisotropy (IMA) may include a ferromagnetic material. In some example embodiments, the magnetic pattern that forms the reference layer among the first magnetic pattern 130 and the second magnetic pattern 150 may further include an antiferromagnetic material for fixing the magnetization direction of the ferromagnetic material.

In some example embodiments, each of the first magnetic pattern 130 and the second magnetic pattern 150 may include a Co-based Heusler alloy.

The tunnel barrier pattern 140 may be provided as an insulating tunnel barrier for generating quantum mechanical tunneling between the first magnetic pattern 130 and the second magnetic pattern 150. The tunnel barrier pattern 140 may include, for example, but is not limited to, at least one of magnesium (Mg) oxide, aluminum (Al) oxide, magnesium-zinc (Mg—Zn) oxide, magnesium-boron (Mg—B) oxide, silicon (Si) oxide, tantalum (Ta) oxide, silicon nitride (SiN), aluminum nitride (AlN), or any combination thereof. As an example, the tunnel barrier pattern 140 may include a magnesium oxide film (MgO film) having a face-centered cubic (FCC) crystal structure or a sodium chloride (NaCl) crystal structure.

The magnetic tunnel junction element ME may store data in each memory cell MC, by utilizing a difference in electrical resistance due to the magnetization direction of the first magnetic pattern 130 and the magnetization direction of the second magnetic pattern 150. In some example embodiments, the magnetic tunnel junction element ME may be provided as a variable resistance element that may be switched between two resistance states by an electrical signal (e.g., a program current) applied thereto. For example, when the magnetization direction of the first magnetic pattern 130 and the magnetization direction of the second magnetic pattern 150 are parallel to each other, the magnetic tunnel junction element ME has a low resistance value, which may be stored as data ‘0’. In contrast, when the magnetization direction of the first magnetic pattern 130 and the magnetization direction of the second magnetic pattern 150 are antiparallel to each other, the magnetic tunnel junction element ME has a high resistance value, which may be stored as data ‘1’.

In some example embodiments, each memory cell MC may have a tapered shape. For example, a width of each memory cell MC (e.g., a width in a horizontal direction, which may include at least one of the X direction or the Y direction) may decrease as it goes away from the base insulating film 120 (e.g., in the Z direction). An inclination angle formed by the side face MCs of each memory cell MC may be, for example, but not limited to, about 60° to about 80° on the basis of the horizontal plane (e.g., XY plane).

The lower electrode pattern BE may be formed on the lower face of the magnetic tunnel junction element ME. The lower electrode pattern BE may be interposed between the base insulating film 120 and the magnetic tunnel junction element ME. Each memory cell MC may be electrically connected to the first transistor TR1 through the lower electrode pattern BE. For example, a contact plug 125 which penetrates the base insulating film 120 and the etching stop film 115 to connect the lower wiring structure LS and the lower electrode pattern BE may be formed. Each memory cell MC may be connected to the second source/drain region 101b through the contact plug 125, the lower wiring structure LS, and the contact pattern CP.

The lower electrode pattern BE may include, for example, but is not limited to, a conductive metal (e.g., titanium, tantalum, ruthenium, or tungsten, etc.) and/or a conductive metal nitride (e.g., titanium nitride or tantalum nitride, etc.).

The upper electrode pattern TE may be formed on the upper face MEt of the magnetic tunnel junction element ME. The upper electrode pattern TE may be interposed between the magnetic tunnel junction element ME and the first conductive line 190. Each memory cell MC may be electrically connected to the first conductive line 190 through the upper electrode pattern TE.

The upper electrode pattern TE may include, for example, but is not limited to, a conductive metal (e.g., titanium, tantalum, ruthenium, or tungsten, etc.) and/or a conductive metal nitride (e.g., titanium nitride or tantalum nitride, etc.).

The capping structure 160 may be formed on the base insulating film 120 and the plurality of memory cells MC. The capping structure may not extend along (e.g., may not overlap in the third direction Z) an upper face of the lower insulating film 110 on the second region II. The capping structure 160 may include a first capping film 162, a second capping film 164, and a third capping film 166 which are sequentially stacked on the side faces MCs of each memory cell MC, which may include being sequentially stacked on a side face MEs of a magnetic tunnel junction element ME.

The first capping film 162 may extend along the upper face 120t of the base insulating film 120 and the side faces MCs of each memory cell MC. Specifically, the first capping film 162 may extend conformally along the profile of the side face BEs of the lower electrode pattern BE, the side face MEs of the magnetic tunnel junction element ME, and the side face TEs of the upper electrode pattern TE. The first capping film 162 may further extend along the upper face 120t of the base insulating film 120 located between the memory cells MC. For example, as shown in FIG. 3, the memory cells MC may include a first memory cell MC1 and a second memory cell MC2 that are arranged along the first direction X. The first capping film 162 may extend conformally along the profile of the upper face 120t of the base insulating film 120 between the first memory cell MC1 and the second memory cell MC2. In some example embodiments, for example, as shown in FIG. 5, the memory cells MC may include a first memory cell MC1 and a third memory cell MC3 that are arranged along the second direction Y. The first capping film 162 may extend conformally along the profile of the upper face 120t of the base insulating film 120 between the first memory cell MC1 and the third memory cell MC3.

In some example embodiments, the upper face 120t of the base insulating film 120 located between the memory cells MC may include (e.g., may define) a recess 120r that is concave upward. The first capping film 162 may extend conformally along the profile of the recess 120r.

In some example embodiments, the uppermost end of the first capping film 162 may be higher than or the same as (e.g., at the same level as) the upper face Tet of the upper electrode pattern TE in the third direction Z. For example, as shown in FIG. 4, a first height H1 of the uppermost end of the first capping film 162 may be higher than or the same as the height of the upper face of the upper electrode pattern TE, on the basis of the upper face of the second magnetic pattern 150.

As described herein, a level or a height of an element may be understood as a distance, in the vertical direction (e.g., third direction Z), of the element from a reference element, where the reference element, as described herein, may be the substrate 100, an upper face 100t of the substrate 100, an upper face MEt of the magnetic tunnel junction element ME, or the like, and where the vertical direction (e.g., third direction Z) may extend perpendicular to the upper face 100t of the substrate 100. As described herein, where an end, face, and/or surface of an element is described to be an uppermost end, face, and/or surface, the end, face, and/or surface may be a furthest end, face, and/or surface of the element from the reference element (e.g., from the substrate 100, an upper face 100t of the substrate 100, etc.) in the vertical direction (e.g., third direction Z). As described herein, where an end, face, and/or surface of an element is described to be a lowermost end, face, and/or surface, the end, face, and/or surface may be a closest end, face, and/or surface of the element to the reference element (e.g., from the substrate 100, an upper face 100t of the substrate 100, etc.) in the vertical direction (e.g., third direction Z). In example embodiments where an element is described to be higher than another element, the element may be understood to be further than the other element from the reference element in the vertical direction. In example embodiments where an element is described to be lower than another element, the element may be understood to be closer than the other element from the reference element in the vertical direction. In example embodiments where an element is described to be at a same level as another element, the element may be understood to be at a same distance as the other element from the reference element in the vertical direction.

In some example embodiments, the upper face of the first capping film 162 may include a first upper face 162u that is adjacent to the upper face TEt of the upper electrode pattern TE. The height of the first upper face 162u may increase as it goes away (e.g., in a horizontal direction) from the upper electrode pattern TE. The uppermost end of the first upper face 162u may be an uppermost end of the first capping film 162. In some example embodiments, the first upper face 162u may include a concave face that is concave upward.

In some example embodiments, the first upper face 162u may be continuous with the upper face of the upper electrode pattern TE. For example, the height of the first upper face 162u that is adjacent to the upper face of the upper electrode pattern TE may be equal to the height of the upper face of the upper electrode pattern TE. In this specification, the term “same” means not only exactly the same thing but also includes a slight difference that may occur duc to a process margin, or the like.

The second capping film 164 may be formed on the first capping film 162. The second capping film 164 may extend conformally along a profile of a side face of the first capping film 162. The second capping film 164 may expose a part of the first capping film 162 that extends along the base insulating film 120 between the memory cells MC. For example, the second capping film 164 may not extend along at least a part of the upper face of the base insulating film 120 located between the memory cells MC.

In some example embodiments, the uppermost end of the second capping film 164 may be higher than the upper face of the upper electrode pattern TE in the third direction Z. In some example embodiments, the uppermost end of the second capping film 164 may be higher than the uppermost end of the first capping film 162 in the third direction Z. For example, as shown in FIG. 4, a second height H2 of the uppermost end of the second capping film 164 may be greater than the first height H1 of the uppermost end of the first capping film 162, on the basis of the upper face of the second magnetic pattern 150.

In some example embodiments, the second capping film 164 may include a second upper face 164u1 adjacent to the first upper face 162u of the first capping film 162, and a third upper face 164u2 adjacent to the second upper face 164u1. A height of the second upper face 164u1 may increase as it goes away (e.g., in a horizontal direction) from the first capping film 162. A height of the third upper face 164u2 may decrease as it goes away (e.g., in a horizontal direction) from the first capping film 162. An intersection line between the second upper face 164u1 and the third upper face 164u2 may be the uppermost end of the second capping film 164. In some example embodiments, the second upper face 164u1 may include a concave face that is concave upward. In some example embodiments, the third upper face 164u2 may include a convex surface that is convex upward.

In some example embodiments, the second upper face 164u1 of the second capping film 164 may be continuous with the first upper face 162u of the first capping film 162. The second capping film 164 may include an inner face 164s1 that is opposite to the first capping film 162. In some example embodiments, the first capping film 162 may completely cover the inner face 164s1 of the second capping film 164.

The third capping film 166 may be formed on the second capping film 164. The third capping film 166 may extend conformally along the profile of the side face (e.g., an outer face 164s2) of the second capping film 164. The third capping film 166 may expose (e.g., in the third direction Z) a part of the first capping film 162 that extends along the base insulating film 120 between the memory cells MC. For example, the third capping film 166 may not extend along the upper face 120t of the base insulating film 120 located between the memory cells MC.

In some example embodiments, the uppermost end of the third capping film 166 may be lower than the upper face TEt of the upper electrode pattern TE in the third direction Z. In some example embodiments, the uppermost end of the third capping film 166 may be lower than the uppermost end of the first capping film 162 in the third direction Z. For example, as shown in FIG. 4, a third height H3 of the uppermost end of the third capping film 166 may be smaller than the first height H1 of the uppermost end of the first capping film 162 on the basis of the upper face 150t of the second magnetic pattern 150 (which may define the upper face Met of the magnetic tunnel junction element ME).

In some example embodiments, the upper face of the third capping film 166 may not be continuous with (e.g., may be spaced apart from) the upper face of the second capping film 164 (e.g., the third upper face 164u2). The second capping film 164 may include an outer face 164s2 that is opposite to the third capping film 166. In some example embodiments, the third capping film 166 may expose an upper part of the outer face 164s2 of the second capping film 164.

In some example embodiments, the second capping film 164 may further extend along a part of the upper face of the base insulating film 120 located between the memory cells MC. For example, as shown in FIG. 4, the lower part of the second capping film 164 may be interposed (e.g., in the third direction Z) between the upper face of the first capping film 162 and the lower face of the third capping film 166. In some example embodiments, the cross section of the lower part of the second capping film 164 may be continuous with the outer face of the third capping film 166.

Each of the first capping film 162 and the third capping film 166 may include at least one of an insulating material, for example, but not limited to, at least one of silicon nitride, silicon oxynitride, silicon oxycarbide, silicon boron nitride, silicon boron carbonitride, silicon oxycarbonitride, or any combinations thereof. In some example embodiments, each of the first capping film 162 and the third capping film 166 may include at least one of a silicon oxide film or a silicon nitride film.

In some example embodiments, each of the first capping film 162 and the third capping film 166 may include the same material film or a substantially same material film as each other. As an example, each of the first capping film 162 and the third capping film 166 may include a silicon nitride film.

The second capping film 164 may include a material film different from the first capping film 162 and the third capping film 166. For example, the second capping film 164 may include a material that is not included in either of (e.g., is absent from each of) the first capping film 162 or the third capping film 166; thus, the second capping film 164 may include a material different from respective materials of the first capping film 162 and the third capping film 166. For example, the second capping film 164 may include at least one of a metal oxide film or a metal nitride film (which may not be included in either of the first capping film 162 or the third capping film 166). The metal element included in the second capping film 164 may include, but is not limited to, at least one of aluminum (Al), titanium (Ti), or tantalum (Ta). As an example, the second capping film 164 may include an aluminum oxide film.

The filling insulating film 180 may be formed on the capping structure 160. The filling insulating film 180 may fill a space between the memory cells MC. The filling insulating film 180 may include, but is not limited to, at least one of silicon oxide, silicon nitride, silicon oxynitride, silicon oxycarbide, silicon boron nitride, silicon boron carbonitride, silicon oxycarbonitride, a low dielectric constant material having a lower dielectric constant than silicon oxide, or any combinations thereof. As an example, the filling insulating film 180 may include a silicon oxide film.

The first conductive line 190 may be formed on the plurality of memory cells MC (e.g., on the upper electrode pattern TE thereof) and the capping structure 160 and may be connected to (e.g., in direct contact with, electrically connected to, etc.) the upper electrode pattern TE of one or more (or each) of the plurality of memory cells MC. The first conductive line 190 may extend in the first direction X. For example, a first trench 180t extending in the first direction X may be formed inside the filling insulating film 180. The first trench 180t may expose an upper face TEt of the upper electrode pattern TE. The first conductive line 190 may be formed inside the first trench 180t and connected to (e.g., in direct contact with) the upper electrode pattern TE. In some example embodiments, the first conductive line 190 may be provided as a bit line (BL of FIG. 1) of the magnetic memory device.

The plurality of first conductive lines 190 may be spaced apart from one another and arranged along the second direction Y. One first conductive line 190 extending in the first direction X may be commonly connected to a plurality of memory cells MC (e.g., a first memory cell MC and a second memory cell MC) arranged along the first direction X.

In some example embodiments, the lowermost face of the first trench 180t may be lower than the upper face of the upper electrode pattern TE. In some example embodiments, the lowermost face of the first trench 180t may be coplanar with the upper face of the third capping film 166.

The first conductive line 190 may be in direct contact with the capping structure 160. In some example embodiments, the first conductive line 190 may be in direct contact with the upper face (e.g., first upper face 162u) of the first capping film 162, an upper face (e.g., a second upper face 164u1 and a third upper face 164u2) and the outer face 164s2 of the second capping film 164, and the upper face of the third capping film 166.

In some example embodiments, the first conductive line 190 may include a first barrier conductive film 192 and a first filling conductive film 194 that are stacked sequentially. The first barrier conductive film 192 may extend conformally along the profile of the first trench 180t. The first barrier conductive film 192 may include a metal or metal nitride for reducing, minimizing, or preventing diffusion of the first filling conductive film 194 (e.g., configured to reduce, minimize, or prevent such diffusion). For example, the first barrier conductive film 192 may include, but is not limited to, at least one of titanium (Ti), tantalum (Ta), tungsten (W), nickel (Ni), cobalt (Co), platinum (Pt), alloys thereof, or nitrides thereof. The first filling conductive film 194 may fill the region of the first conductive line 190 that remains after the first barrier conductive film 192 is formed. The first filling conductive film 194 may include, but is not limited to, at least one of aluminum (Al), copper (Cu), tungsten (W), molybdenum (Mo), cobalt (Co), ruthenium (Ru), or alloys thereof.

The upper insulating film 280 may be formed on the etching stop film 115 on the second region II. The upper insulating film 280 may include, but not limited to, at least one of, for example, silicon oxide, silicon nitride, silicon oxynitride, silicon oxycarbide, silicon boron nitride, silicon boron carbonitride, silicon oxycarbonitride, a low dielectric constant material having a lower dielectric constant than silicon oxide, or any combinations thereof.

The upper wiring structure US may be formed on the upper insulating film 280. The upper wiring structure US may include upper wiring patterns UW and upper via patterns UV. The upper wiring patterns UW may extend in a horizontal direction (e.g., the first direction X or the second direction Y). For example, a second trench 280t extending in the second direction Y may be formed inside the upper insulating film 280. The upper wiring patterns UW may be formed inside the second trench 280t. The upper via patterns UV may electrically connect the lower wiring structure LS and the upper wiring patterns UW. For example, a via hole 280h that extends from the lower face of the second trench 280t and penetrates the upper insulating film 280 and the etching stop film 115 may be formed. The upper via patterns UV may be formed inside the via hole 280h and connected to the lower wiring structure LS. The number (e.g., quantity), placement and the like of the upper wiring patterns UW and the upper via patterns UV as shown in the drawings are merely examples and are not limited to those shown in the drawings. Also, the upper wiring patterns UW are shown only to extend in the second direction Y, but this is merely example.

In some example embodiments, the lower face of the second trench 280t may be lower than the lowermost face of the first trench 180t.

In some example embodiments, each upper wiring pattern UW and each upper via pattern UV may include a second barrier conductive film 292 and a second filling conductive film 294 that are stacked sequentially. The second barrier conductive film 292 may extend conformally along the profile of the second trench 280t and the via hole 280h. The second barrier conductive film 292 may include a metal or metal nitride for reducing, minimizing, or preventing diffusion of the second filling conductive film 294 (e.g., configured to reduce, minimize, or prevent such diffusion). For example, the second barrier conductive film 292 may include, but is not limited to, at least one of titanium (Ti), tantalum (Ta), tungsten (W), nickel (Ni), cobalt (Co), platinum (Pt), alloys thereof, or nitrides thereof. The second filling conductive film 294 may fill the region of the upper wiring patterns UW and the region of the upper via patterns UV that remain after the second barrier conductive film 292 is formed. The second filling conductive film 294 may include, but is not limited to, at least one of aluminum (Al), copper (Cu), tungsten (W), molybdenum (Mo), cobalt (Co), ruthenium (Ru), or alloys thereof.

In some example embodiments, the first barrier conductive film 192 and the second barrier conductive film 292 may be formed at the same level as each other. In some example embodiments, the first and second filling conductive films 194 and 294 may be formed at the same level as each other.

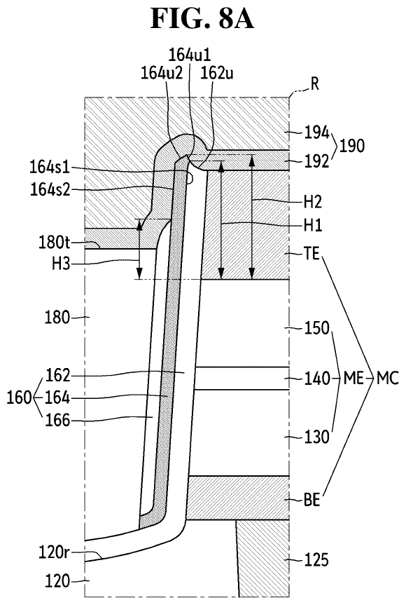

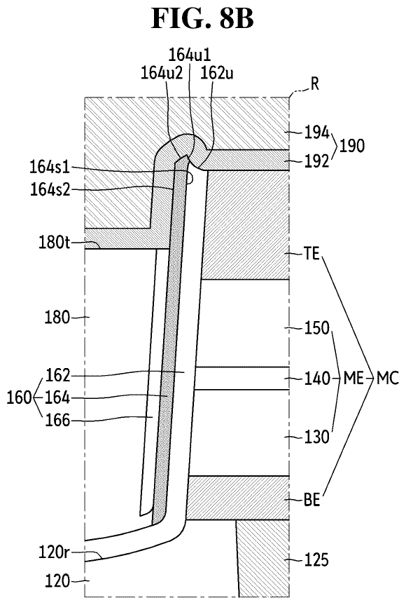

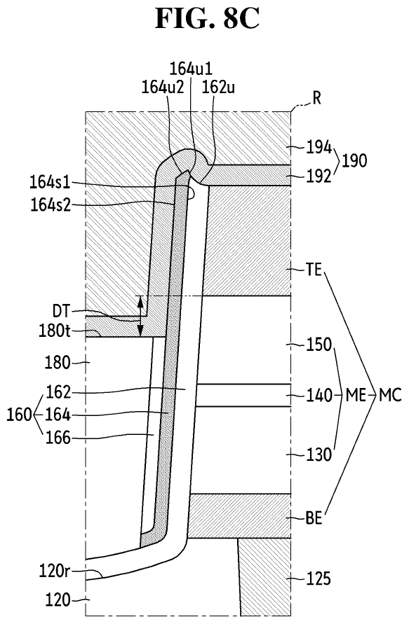

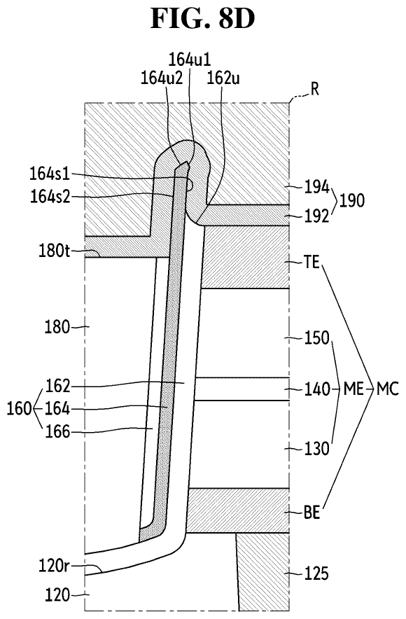

FIGS. 8A, 8B, 8C, and 8D are various enlarged views for explaining a magnetic memory device according to some example embodiments. For convenience of explanation, repeated parts of those explained above using FIGS. 1 to 7 will be briefly described or omitted.

Referring to FIG. 8A, in the magnetic memory device according to some example embodiments, the uppermost end of the third capping film 166 may be higher than the lowermost face of the first trench 180t.

For example, as shown in FIG. 8A, and unlike the third capping film 166 of FIG. 4, the upper part of the third capping film 166 may protrude above the lowermost face of the first trench 180t. In some example embodiments, the upper face of the third capping film 166 may include a convex face that is convex upward.

Referring to FIG. 8B, in the magnetic memory device according to some example embodiments, a part of the filling insulating film 180 may be interposed between the first capping film 162 and the third capping film 166.

For example, as shown in FIG. 8B, and unlike the second capping film 164 of FIG. 4, the lower part of the second capping film 164 may be recessed inward beyond the outer face of the third capping film 166. A part of the filling insulating film 180 may fill the recessed region of the second capping film 164.

Referring to FIG. 8C, in the magnetic memory device according to some example embodiments, the lowermost face of the first trench 180t is lower than the lower face of the upper electrode pattern TE.

For example, as shown in FIG. 8C, and unlike the first trench 180t of FIG. 4, the lowermost face of the first trench 180t may be located to be lower than the upper face of the second magnetic pattern 150. A depth DT at which the lowermost face of the first trench 180t is formed is only shown to be smaller than the thickness of the second magnetic pattern 150 on the basis of the lower face of the upper electrode pattern TE, but this is merely an example. In some cases, the lowermost face of the first trench 180t may be located to be lower than the upper face of the tunnel barrier pattern 140 or may be located to be lower than the upper face of the first magnetic pattern 130.

Referring to FIG. 8D, in the magnetic memory device according to some example embodiments, the first capping film 162 exposes an upper part of the inner face 164s1 of the second capping film 164.

For example, as shown in FIG. 8D, and unlike the first capping film 162 of FIG. 4, the upper face of the first capping film 162 (e.g., the first upper face 162u) may not be continuous with the upper face of the second capping film 164 (e.g., the first upper face 164u1). In some example embodiments, the first upper face 162u may be continuous with the upper face of the upper electrode pattern TE.

Hereinafter, a method for fabricating a magnetic memory device according to some example embodiments will be described referring to FIGS. 1 to 17.

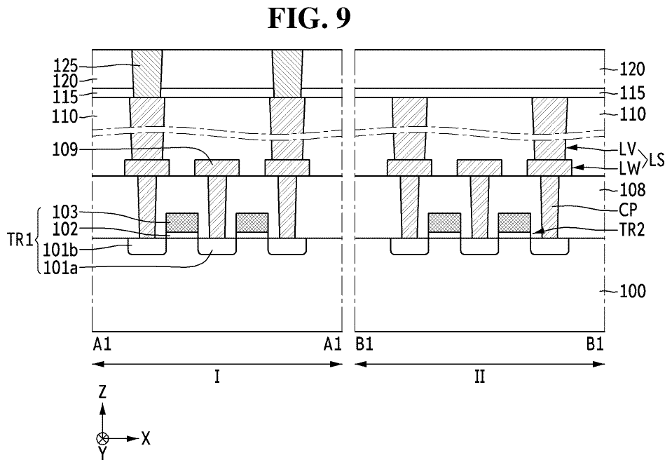

FIGS. 9, 10, 11, 12, 13, 14, 15, 16 and 17 are intermediate step diagrams for explaining the method for fabricating the magnetic memory device according to some example embodiments. For convenience of description, repeated parts of those explained above using FIGS. 1 to 8 will be briefly described or omitted.

Referring to FIG. 9, a first transistor TR1, a second transistor TR2, an interlayer insulating film 108, a contact pattern CP, a lower insulating film 110, a lower wiring structure LS, an etching stop film 115, a base insulating film 120, and a contact plug 125 are formed on the substrate 100.

For example, the first transistor TR1 may be formed on a first region I of the substrate 100, and the second transistor TR2 may be formed on a second region II of the substrate 100. Next, an interlayer insulating film 108 that covers the first transistor TR1 and the second transistor TR2 may be formed on the substrate 100. Next, a contact pattern CP that penetrates the interlayer insulating film 108 and is connected to the first transistor TR1 and/or the second transistor TR2 may be formed. Next, the lower insulating film 110 may be formed on the interlayer insulating film 108, and the lower wiring structure LS connected to the contact pattern CP may be formed inside the lower insulating film 110. Next, the etching stop film 115 and the base insulating film 120 may be sequentially formed on the lower insulating film 110. Next, the contact plug 125 that penetrates the etching stop film 115 and the base insulating film 120 and is connected to the lower wiring structure LS may be formed on the first region I.

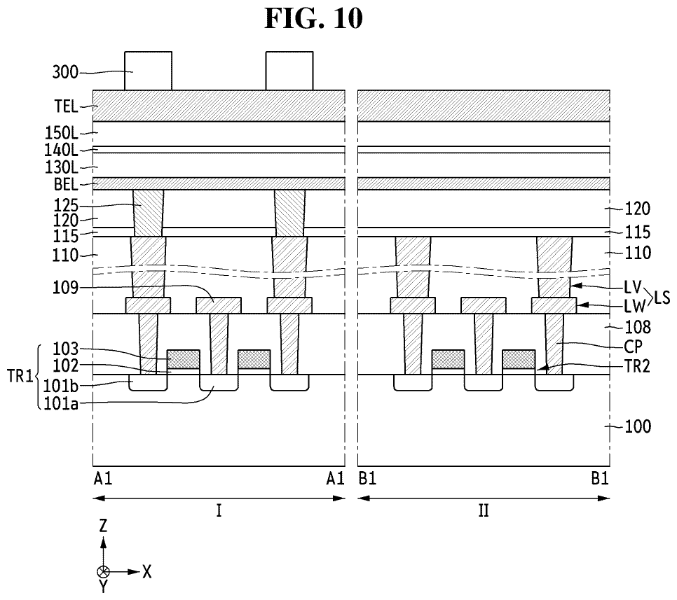

Referring to FIG. 10, a lower electrode film BEL, a first magnetic film 130L, a tunnel barrier film 140L, a second magnetic film 150L, an upper electrode film TEL, and a mask pattern 300 are sequentially formed on the base insulating film 120.

The lower electrode film BEL may extend along the upper face of the base insulating film 120. The lower electrode film BEL may be electrically connected to the contact plug 125. The lower electrode film BEL may include, for example, but is not limited to, a conductive metal (e.g., titanium, tantalum, ruthenium, or tungsten) or a conductive metal nitride (e.g., titanium nitride or tantalum nitride).

The first magnetic film 130L, the tunnel barrier film 140L, and the second magnetic film 150L may be sequentially stacked on the lower electrode film BEL. One of the first magnetic film 130L or the second magnetic film 150L may be a reference layer having a fixed magnetization direction regardless of an external magnetic field, and the other of the first magnetic film 130L or the second magnetic film 150L may be a free layer that is variable between two stable magnetization directions. The tunnel barrier film 140L may be provided as an insulated tunnel barrier that generates quantum mechanical tunneling between the first magnetic film 130L and the second magnetic film 150L.

The upper electrode film TEL may be stacked on the second magnetic film 150L. The upper electrode film TEL may include, but not limited to, a conductive metal (e.g., titanium, tantalum, ruthenium or tungsten) or a conductive metal nitride (e.g., titanium nitride or tantalum nitride).

The mask pattern 300 may be formed on the upper electrode film TEL. The mask pattern 300 may be formed to correspond to a position at which the contact plug 125 is disposed. The mask pattern 300 may include, but not limited to, a photoresist pattern and/or a hard mask pattern.

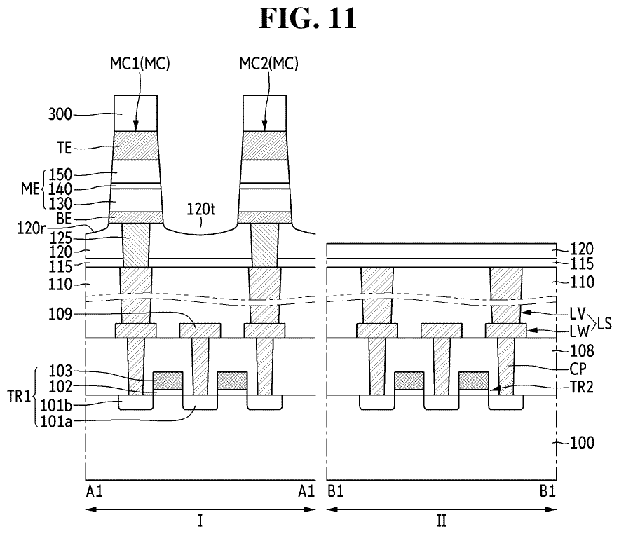

Referring to FIG. 11, a plurality of memory cells MC are formed.

For example, an etching process which uses the mask pattern 300 as an etching mask may be performed. As the etching process is performed, the lower electrode film BEL, the first magnetic film 130L, the tunnel barrier film 140L, the second magnetic film 150L, and the upper electrode film TEL of FIG. 10 may be patterned. Accordingly, a plurality of memory cells MC including the lower electrode pattern BE, the magnetic tunnel junction element ME, and the upper electrode pattern TE may be formed. The etching process may include, for example, but is not limited to, an ion beam etching process. After the memory cells MC are formed, the mask pattern 300 may be removed.

In some example embodiments, as the etching process is performed, a part of the base insulating film 120 located between the memory cells MC may be removed. As a result, the upper face 120t of the base insulating film 120 located between the memory cells MC may include a recess 120r that is concave upward.

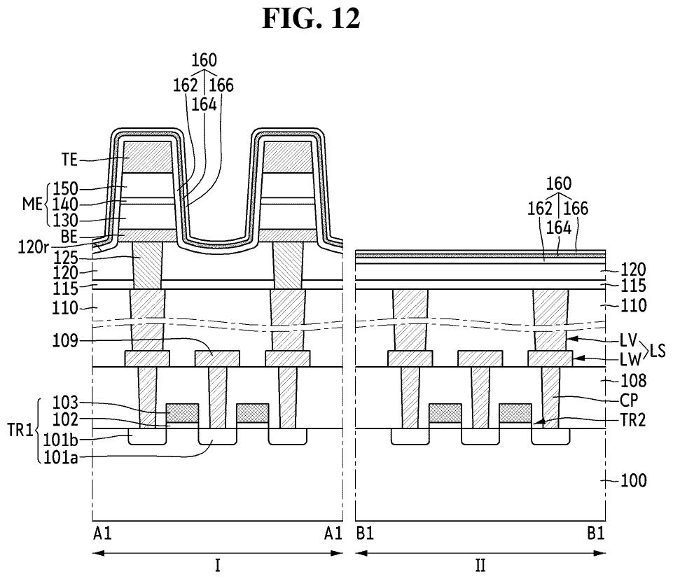

Referring to FIG. 12, a capping structure 160 is formed on the base insulating film 120 and the memory cell MC.

The capping structure 160 may include a first capping film 162, a second capping film 164, and a third capping film 166 that are sequentially stacked on the base insulating film 120 and the memory cells MC. For example, the first capping film 162 may extend conformally along the profile of the upper face of the base insulating film 120 and the side face and upper face of each memory cell MC. The second capping film 164 may extend conformally along the profile of the first capping film 162. The third capping film 166 may extend conformally along the profile of the second capping film 164.

The second capping film 164 may have an etching selectivity different from that of the first capping film 162 and the third capping film 166. For example, the first capping film 162 and the third capping film 166 may each have a high selectivity in a dry etching process, in comparison with the second capping film 164. Also, for example, the second capping film 164 may have a high selectivity in a wet etching process in comparison with the first capping film 162 and the third capping film 166. The second capping film 164 may include a material that is different from the respective materials of the first capping film 162 and the third capping film 166 (e.g., the second capping film 164 may include a material that is not included in either of the first capping film 162 or the third capping film 166). As an example, each of the first capping film 162 and the third capping film 166 may include a silicon nitride film, and the second capping film 164 may include an aluminum oxide film.

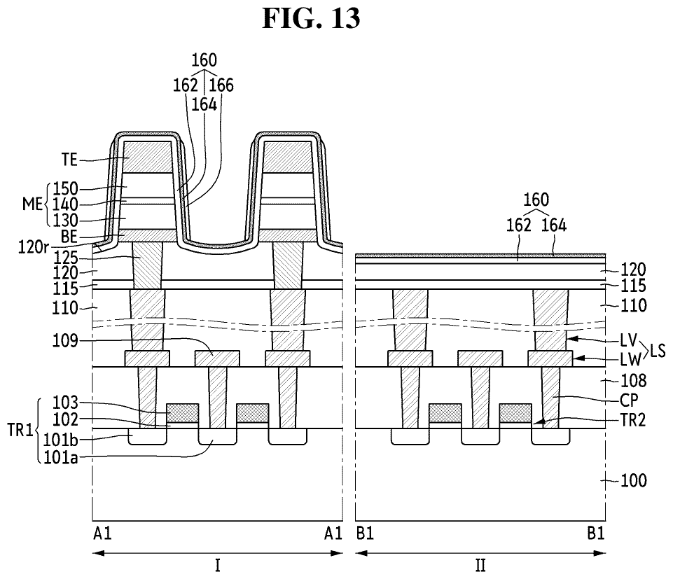

Referring to FIG. 13, a first etching process is performed on the third capping film 166.

In the first etching process, the third capping film 166 may have a higher selectivity in comparison with the second capping film 164. In some example embodiments, the first etching process may include an anisotropic etching process having vertical direction (e.g., third direction Z) characteristics. For example, the first etching process may include a dry etching process performed in the third direction Z. As the first etching process is performed, a part of the third capping film 166 having a predominant horizontal component may be removed, and another part of the third capping film 166 having a predominant vertical component may remain. As a result, the third capping film 166 extending along the side face of the second capping film 164 may be formed. Also, at least a part of the upper face of the second capping film 164 may be exposed from the third capping film 166. For example, the second capping film 164 on the upper face of each memory cell MC and the second capping film 164 on the upper face of the base insulating film 120 located between the memory cells MC may be exposed.

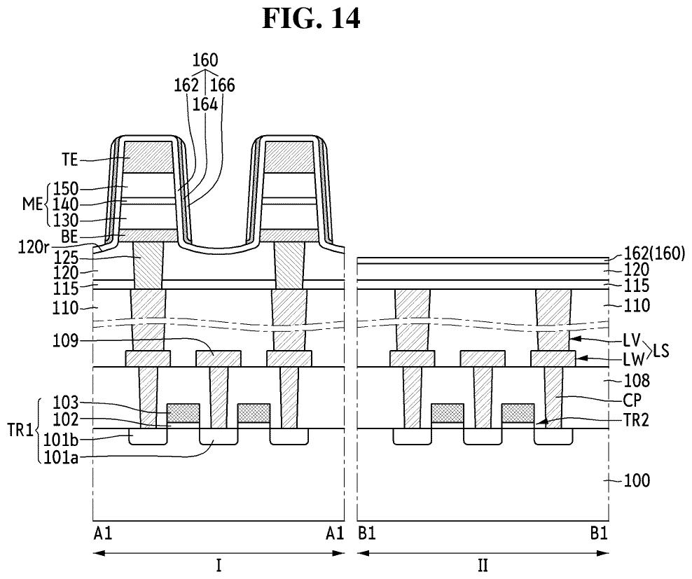

Referring to FIG. 14, the second etching process is performed on the second capping film 164.

In the second etching process, the second capping film 164 may have a higher selectivity in comparison with the first capping film 162 and the third capping film 166. In some example embodiments, the second etching process may include an isotropic etching process. For example, the second etching process may include a wet etching process. As the second etching process is performed, at least a part of the second capping film 164 exposed from the third capping film 166 may be removed. As a result, the second capping film 164 extending along the side face of the first capping film 162 may be formed. Also, at least a part of the upper face of the first capping film 162 may be exposed from the second capping film 164. For example, the first capping film 162 on the upper face of each memory cell MC, and the first capping film 162 on the upper face of the base insulating film 120 located between the memory cells MC may be exposed.

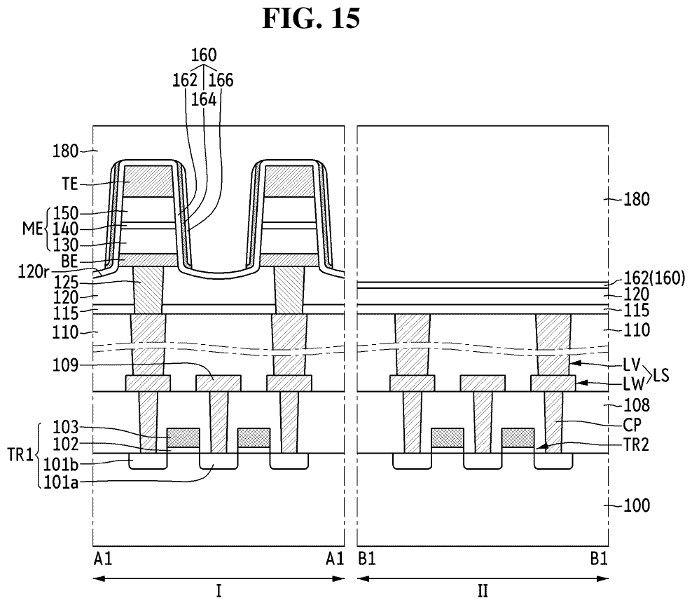

Referring to FIG. 15, a filling insulating film 180 is formed.

The filling insulating film 180 may be formed on the capping structure 160. The filling insulating film 180 may fill a space between the memory cells MC.

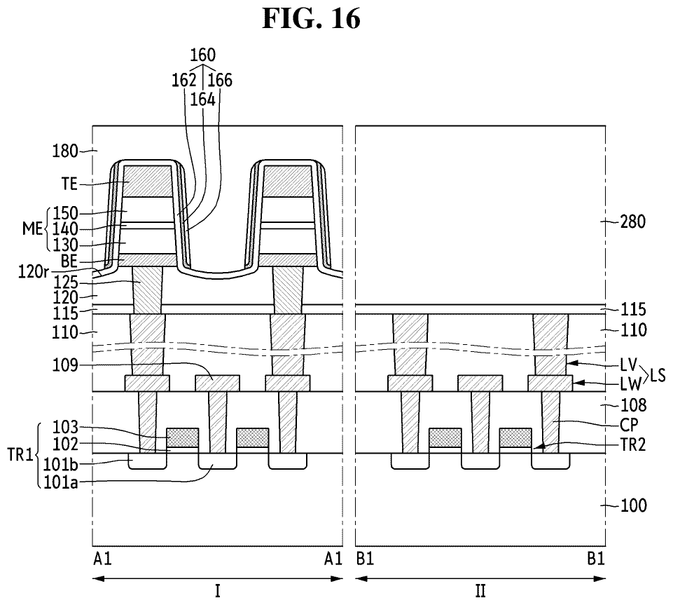

Referring to FIG. 16, an upper insulating film 280 is formed on the etching stop film 115 on the second region II.

For example, the base insulating film 120, the etching stop film 115, and the filling insulating film 180 on the second region II may be removed. Next, an upper insulating film 280 which replaces the region from which the base insulating film 120, the etching stop film 115, and the filling insulating film 180 are removed may be formed.

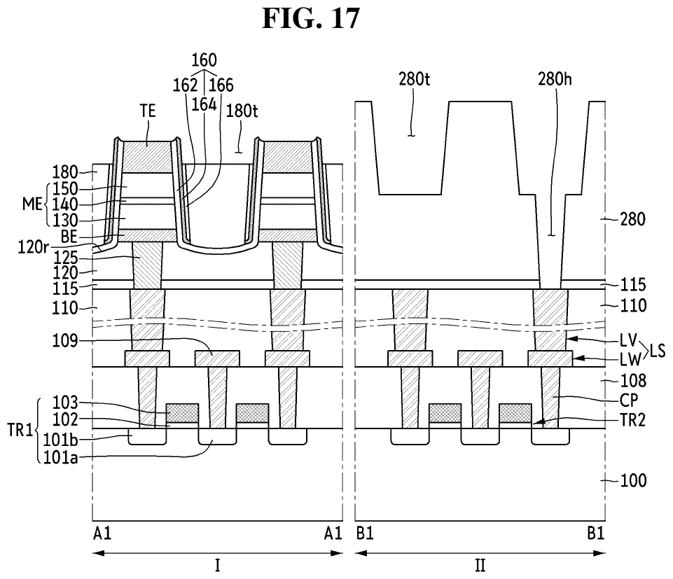

Referring to FIG. 17, a third etching process is performed on the filling insulating film 180.

In the third etching process, the first capping film 162 and the third capping film 166 may have a higher selectivity in comparison with the second capping film 164. For example, the third etching process may include a dry etching process. In the course in which the third etching process is performed, the upper part of the first capping film 162 and the upper part of the third capping film 166 may be removed. Thus, a first trench 180t that exposes the upper face of the upper electrode pattern TE may be formed inside the filling insulating film 180. In some example embodiments, the lowermost face of the first trench 180t may be formed to be lower than the upper face of the upper electrode pattern TE. Also, in the course in which the third etching process is performed, the second capping film 164 may protect the first capping film 162 on the side face of each memory cell MC.

In some example embodiments, the via hole 280h and/or the second trench 280t may be formed at the same level as the first trench 180t. For example, the via hole 280h and/or the second trench 280t may be formed by a third etching process. In some example embodiments, the lower face of the second trench 280t may be lower than the lowermost face of the first trench 180t. This may be due to, but not limited to, a loading effect that occurs in the third etching process.

Next, referring to FIG. 3, the first conductive line 190 and the upper wiring structure US are formed. Accordingly, the magnetic memory device described above using FIGS. 2 to 7 may be fabricated.

As the downscaling of magnetic memory devices continues to progress, control of the etching amount of the etching process has become an issue. For example, over-etching of the capping film that covers the memory cell MC may be induced in the course of forming the first trench 180t to form the first conductive line 190. Such over-etching increases the risk of short between the side face of the magnetic tunnel junction element ME and the first conductive line 190, which causes a decrease in the characteristics and yield of the magnetic memory device.

In contrast, the magnetic memory device according to some example embodiments may prevent short between the side face MEs of the magnetic tunnel junction element ME and the first conductive line 190, or reduce or minimize the risk of such a short between the side face MEs of the magnetic tunnel junction element ME and the first conductive line 190, using the capping structure 160 including the first capping film 162, the second capping film 164, and the third capping film 166 (e.g., based on the magnetic memory device including the capping structure 160 including the first capping film 162, the second capping film 164, and the third capping film 166 that are sequentially stacked on the side face MEs of the magnetic tunnel junction element ME). Specifically, as described above, the second capping film 164 interposed between the first capping film 162 and the third capping film 166 may have a different etching selectivity from the first capping film 162 and the third capping film 166 (e.g., based on the second capping film 164 including a material different from respective materials of the first capping film 162 and the third capping film 166, for example such that the second capping film 164 includes a material that is not included in either of the first capping film 162 or the third capping film 166). Also, as described above, such a second capping film 164 may protect the first capping film 162 on the side face of each memory cell MC in the course of forming the first trench 180t. As a result, the side face MEs of the magnetic tunnel junction element ME may protected despite the over-etching, based on the magnetic memory device including the capping structure 160 including the first capping film 162, the second capping film 164, and the third capping film 166 that are sequentially stacked on the side face MEs of the magnetic tunnel junction element ME, and a magnetic memory device with improved element characteristics and process margins, and which may have reduced risk of process defects and/or shorts (e.g., reduced, minimized, or prevented risk of shorts between the side face MEs of the magnetic tunnel junction element ME and the first conductive line 190) and thus may have improved reliability and/or defect-free manufacturing yield, may be provided.

Although some example embodiments of the present inventive concepts have been described with reference to the accompanying drawings, the present inventive concepts are not limited to such example embodiments but may be implemented in various different forms. A person skilled in the art may appreciate that the present inventive concepts may be practiced in other concrete forms without changing the technical spirit or essential characteristics of the present inventive concepts. Therefore, it should be appreciated that the example embodiments as described above is not restrictive but illustrative in all respects.

What is claimed is:

1. A magnetic memory device, comprising:
a substrate;
a base insulating film on the substrate;
a magnetic tunnel junction element, the magnetic tunnel junction element including a first magnetic pattern, a tunnel barrier pattern, and a second magnetic pattern that are sequentially stacked on the base insulating film;
an upper electrode pattern on an upper face of the magnetic tunnel junction element;
a capping structure, the capping structure including a first capping film, a second capping film, and a third capping film that are sequentially stacked on a side face of the magnetic tunnel junction element; and
a conductive line on both the upper electrode pattern and the capping structure, the conductive line connected to the upper electrode pattern,
wherein an uppermost end of the second capping film is higher than an uppermost end of the first capping film,
wherein an uppermost end of the third capping film is lower than the uppermost end of the first capping film, and
wherein the second capping film includes a material different from respective materials of the first capping film and the third capping film.

2. The magnetic memory device of claim 1, wherein
the first capping film further extends along an upper face of the base insulating film, and
the second capping film and the third capping film expose a part of the first capping film extending along the upper face of the base insulating film.

3. The magnetic memory device of claim 1, wherein the uppermost end of the first capping film is higher than or at a same level as an upper face of the upper electrode pattern.

4. The magnetic memory device of claim 1, wherein the uppermost end of the second capping film is higher than an upper face of the upper electrode pattern.

5. The magnetic memory device of claim 1, wherein the uppermost end of the third capping film is lower than an upper face of the upper electrode pattern.

6. The magnetic memory device of claim 1, wherein the conductive line is in direct contact with an upper face of the first capping film, an upper face of the second capping film, an outer face of the second capping film, and an upper face of the third capping film.

7. The magnetic memory device of claim 1, wherein each of the first capping film and the third capping film includes at least one of a silicon oxide film or a silicon nitride film.

8. The magnetic memory device of claim 7, wherein the first capping film and the third capping film include a same material film as each other.

9. The magnetic memory device of claim 1, wherein the second capping film includes at least one of a metal oxide film or a metal nitride film.

10. The magnetic memory device of claim 9, wherein the second capping film includes an aluminum oxide film.

11. A magnetic memory device, comprising:
a substrate;
a base insulating film on the substrate;
a first memory cell and a second memory cell, the first memory cell and the second memory cell spaced apart from each other on the base insulating film, the first memory cell and the second memory cell each including a magnetic tunnel junction element and an upper electrode pattern that are sequentially stacked on the base insulating film;
a capping structure, the capping structure including a first capping film, a second capping film, and a third capping film that are sequentially stacked on both a side face of the first memory cell and a side face of the second memory cell; and
a conductive line on the first memory cell and the second memory cell, the conductive line connected to both the upper electrode pattern of the first memory cell and the upper electrode pattern of the second memory cell,
wherein the first capping film further extends along an upper face of the base insulating film between the first memory cell and the second memory cell,
wherein the second capping film and the third capping film expose a part of the first capping film extending along the upper face of the base insulating film, and
wherein the second capping film includes a material different from respective materials of the first capping film and the third capping film.

12. The magnetic memory device of claim 11, wherein an uppermost end of the first capping film is higher than or at a same level as an upper face of at least one of the upper electrode pattern of the first memory cell or the upper electrode pattern of the second memory cell.

13. The magnetic memory device of claim 12, wherein an uppermost end of the second capping film is higher than the uppermost end of the first capping film.

14. The magnetic memory device of claim 12, wherein an uppermost end of the third capping film is lower than the uppermost end of the first capping film.

15. The magnetic memory device of claim 11, wherein
the upper face of the base insulating film between the first memory cell and the second memory cell includes a recess that is concave upward, and
the first capping film extends along a profile of the recess.

16. The magnetic memory device of claim 11, wherein
each of the first capping film and the third capping film includes a silicon nitride film, and
the second capping film includes an aluminum oxide film.

17. A magnetic memory device, comprising:
a substrate including a first region and a second region;
a first transistor on the first region;
a second transistor on the second region;
a lower insulating film on both the first transistor and the second transistor;
a base insulating film on the lower insulating film on the first region;
a memory cell, the memory cell including a lower electrode pattern, a magnetic tunnel junction element, and an upper electrode pattern that are sequentially stacked on the base insulating film, the memory cell electrically connected to the first transistor;
a capping structure, the capping structure including a first capping film, a second capping film, and a third capping film that are sequentially stacked on a side face of the memory cell;
a conductive line on the memory cell and the capping structure, the conductive line connected to the upper electrode pattern;
an upper insulating film on the lower insulating film on the second region; and
an upper wiring pattern, the upper wiring pattern electrically connected to the second transistor inside the upper insulating film,
wherein the capping structure does not extend along an upper face of the lower insulating film on the second region, and
wherein the second capping film includes a material different from respective materials of the first capping film and the third capping film.

18. The magnetic memory device of claim 17, wherein
an uppermost end of the first capping film is higher than or at a same level as the upper face of the upper electrode pattern,
an uppermost end of the second capping film is higher than the uppermost end of the first capping film, and
an uppermost end of the third capping film is lower than the uppermost end of the first capping film.

19. The magnetic memory device of claim 17, wherein
the first capping film further extends along an upper face of the base insulating film, and
the second capping film and the third capping film expose a part of the first capping film extending along the upper face of the base insulating film.

20. The magnetic memory device of claim 17, further comprising:
a lower wiring structure inside the lower insulating film; and
a contact plug, the contact plug penetrating the base insulating film, the contact plug connecting the lower wiring structure and the lower electrode pattern.
